(19) United States
(12) Patent Application Publication
(10) Pub. No.: US 2009/0006014 A1
(43) Pub. Date: Jan. 1, 2009

(54) Non-Destructive Electrical Characterization Macro and Methodology for In-Line Interconnect Spacing Monitoring

(75) Inventors: Kaushik Chanda, Fishkill, NY (US); Fen Chen, Williston, VT (US); Paul S. McLaughlin, Poughkeepsie, NY (US); Ernest Y. Wu, Essex Junction, VT (US)

Correspondence Address: GREENBLUM & BERNSTEIN, P.L.C., 1950 ROLAND CLARKE PLACE, RESTON, VA, 20191, US

(73) Assignee: INTERNATIONAL BUSINESS MACHINES CORPORATION, Armonk, NY (US)

(21) Appl. No.: 11/769,265

(22) Filed: Jun. 27, 2007

(51) Int. Cl. G01R 27/26; G01B 21/28

(52) U.S. Cl. 702/65; 702/156

(57) ABSTRACT

A method for determining a line-to-line spacing of a device. The method includes experimentally determining a slope k_{CA}, experimentally determining a slope k_{SE} and determining a line-to-line spacing of a device from the slope k_{CA} and the slope k_{SE}. A structure for performing the method includes a non-destructive line-to-line spacing characterization macro.

### FIELD OF THE INVENTION

The present invention relates to a fast, non-destructive line-to-line spacing determination methodology with combined I-V and C-V measurement and a related testing structure and system, to accurately determine line-to-line spacing for in-line fabrication monitoring and for low-k time dependent dielectric breakdown (TDDB) reliability evaluation.

### BACKGROUND DESCRIPTION

Poor process controls may cause huge line spacing variation across a semiconductor wafer during back-end-of-the-line (BEOL) integration. In consequence, significant degradation in yield, performance, and reliability may be observed. Line spacing variation imposes challenges for accurate time dependent dielectric breakdown (TDDB) reliability lifetime projection.

The minimum spacing between metal-leads in advanced integrated circuits (ICs) continues to decrease with each new generation of technology. In fact, the dielectric thickness between adjacent metal-lines is rapidly decreasing to values (<100 nm). And, with a narrower line spacing there is higher capacitance between line-to-line spacing. This higher capacitance between the line-to-line spacing may create a large potential for cross-talk, where if the spacing is close, a signal of one line may affect the signal of another line. Moreover, if the line spacing is narrower than specification and two lines touch or are too close, the chip may breakdown over time. Additionally, with narrower line spacing, a higher electric field is produced, which may reduce the lifetime of the device.

Due to a desire to lower the line-to-line capacitance, in order to minimize the RC time-delay response of the interconnect network, to minimize the power consumption, and to prevent cross-talk, low dielectric constant (low-k) materials have been introduced as interconnect dielectrics. However, these low-k dielectric materials do not have the dielectric strength of dense amorphous SiO₂ insulators. Rather, the dielectric strength of these low-k dielectric materials is generally degraded by the presence of weaker bonds, e.g., Si—C bonds, greater number of traps, porosity, mobile-ions, etc. Additionally, the higher electric field due to the narrow line spacing may cause the interlevel dielectric between the spacings to breakdown over time.

With the wide application of low-k and ultra low-k dielectric materials, the long term reliability of these materials is rapidly becoming one of the most critical challenges for technology development. Low-k time dependent dielectric breakdown (TDDB) is commonly considered an important reliability issue because low-k materials generally have weaker intrinsic breakdown strength than traditional SiO₂ dielectrics. This problem is further exacerbated by the aggressive shrinking of the interconnect pitch due to continuous technology scaling.

Since low-k TDDB is important for low-k dielectric technology development and lifetime modeling, TDDB stresses are recommended to be performed routinely to assure a robust technology development and an accurate reliability lifetime prediction. However, TDDB test results are very sensitive to line-to-line spacing variation. As all the chips under TDDB test will receive the same stress voltage, the final time-to-fail of each chip is strongly dependent on spacing. Chips with larger spacing will last longer because they see less electric field, but chips with narrower spacing will last shorter because they see a higher electric field. Therefore, such time-to-fail variation caused by spacing will impact an accurate lifetime projection.

Current possible ways for characterization of line spacing for fully integrated wafers includes C-V measurement analysis, double VRDB, and destructive physical analysis, e.g., scanning electron microscopy (SEM) or transmission electron microscopy (TEM). However, there are drawbacks to each of these techniques.

C-V profiling is a technique used for characterization of semiconductor materials and devices. C-V measurement analysis is a simple and non-destructive test for characterization of line spacing for fully integrated wafers. However, with C-V measurement a large low-k area must be tested, i.e., only testing one pair of interconnects may not be sufficient to reach a C-V meter's resolution. That is, the test structure may be many pairs of interconnects, e.g., hundreds, tested together.

Additionally, C-V measurement measures other capacitances of the device, e.g., fringing capacitance, parasitic capacitance, end capacitance, next nearest neighbor capacitance, etc. By accounting for these other capacitances, the C-V measurement for direct line-to-line capacitance may be inaccurate, resulting in an inaccurate line-to-line spacing determination.

Furthermore, a determined C-V capacitance may be misleading due to variations of line spacing and line height (therefore the line area) of a semiconductor device. As capacitance is dependent on both line spacing and line height (area), the resulting calculated capacitance may be the same for different structures if both the line spacing and height vary between test structures. Thus, with a determined C-V profile, it may be difficult to extract an accurate line-to-line spacing, as the C-V variations may be due either to changes in the line-to-line spacing or the changes in the line area. In this way, a C-V profile alone may indicate misleading line-to-line spacing results. Another problem associated with C-V measurement for line spacing measurement is how to determine the dielectric constant. Process changes and new material introductions could lead to a dielectric constant change. Without knowing the exact dielectric constant, spacing could not be accurately determined from C-V measurement.

Double voltage ramp dielectric breakdown (VRDB) tests may also be used to determine a characterization of line-to-line spacing for fully integrated wafers. Using the double VRDB test, two ramp rates are used to extract a line-to-line spacing. More specifically, a first ramp rate is used on one set of chips, and a second ramp rate is used on a second set of chips.

However, there are concerns with the double VRDB test as well. VRDB testing is a destructive test, whereby the two different devices subjected to the testing are destroyed during testing. Additionally, inherent chip-to-chip variation may be a problem. As the two ramp rates are tested on two different sets of devices to generate a single spacing value for both devices, an actual line-to-line spacing is not determined. Rather, using the double VRDB test on two different devices, an average line-to-line spacing is obtained, which may be somewhat inaccurate. That is, chip performance and reliability are best determined from an actual localized spacing, and not from an average spacing.

Furthermore, using a double VRDB test still requires a pre-known TDDB kinetic parameter. Therefore, a time dependent dielectric breakdown (TDDB) test must be performed. More specifically, in order to perform the double VRDB test, a field acceleration factor, γ, must be determined from a TDDB test. Additionally, the TDDB test may require at least two further destructive tests, wherein at least two additional devices are destroyed. Furthermore, using the field acceleration factor, γ, determined from the TDDB test for the VRDB test assumes that TDDB and VRDB follow exactly the same breakdown mechanism. However, experimentation has shown that the field acceleration factor, γ, determined from the TDDB test may not be the same value as that for voltage breakdown in the VRDB test.

Additionally, scanning electron microscopy (SEM) or transmission electron microscopy (TEM) analysis may be used to determine a characterization of line spacing for fully integrated wafers. With SEM, electrons are thermionically emitted from a tungsten or lanthanum hexaboride (LaB₆) cathode and are accelerated towards an anode. When the primary electron beam interacts with the sample, the electrons lose energy by repeated scattering and absorption within a teardrop-shaped volume of the specimen known as the interaction volume. The energy exchange between the electron beam and the sample results in the emission of electrons and electromagnetic radiation which can be detected to produce an image. Additionally, TEM is an imaging technique whereby a beam of electrons is transmitted through a specimen, then an image is formed, magnified and directed to appear either on a fluorescent screen or layer of photographic film (see electron microscope), or to be detected by a sensor such as a CCD camera.

However, there are drawbacks to SEM and TEM techniques as well. More specifically, SEM and TEM techniques are destructive. Thus, an accurate line spacing may be determined for those devices actually measured using SEM or TEM techniques, however, those devices are destroyed. An estimated line-to-line spacing for non-tested devices may be determined from the measured line-to-line spacing of the destroyed device; however, as this is an estimation, the estimated line spacing may be inaccurate. Additionally, SEM and TEM techniques are very time-consuming tests. Furthermore, with SEM and TEM techniques, only a small area of a device is examined, resulting in a very localized analysis.

Accordingly, there exists a need in the art to overcome the deficiencies and limitations described hereinabove.

### SUMMARY OF THE INVENTION

In a first aspect of the invention, a method comprises experimentally determining a slope k_{CA}, experimentally determining a slope k_{SE}, and determining a line-to-line spacing of a device from the slope k_{CA} and the slope k_{SE}.

In a second aspect of the invention, a computer program product comprising a computer usable medium having readable program code embodied in the medium. The computer program product includes at least one component to experimentally determining a slope k_{CA}, experimentally determining a slope k_{SE}, and determining a line-to-line spacing of a device from the slope k_{CA} and the slope k_{SE}.

In a third aspect of the invention, an AreaComb macro structure, comprises a plurality of comb-comb structures. Furthermore, each comb-comb structure comprises first and second parallel bases, a plurality of first combs transversely projecting from the first base towards the second base, and a plurality of second combs transversely projecting from the second base towards the first base, wherein the plurality of first combs are interspaced with the plurality of second combs in an alternating manner.

### BRIEF DESCRIPTION OF THE DRAWINGS

FIG. 1 shows a capacitance versus area curve according to an aspect of the invention;

FIG. 2 shows an I-V curve for devices having a different line-to-line spacing according to an aspect of the invention;

FIG. 3 shows an I-V curve for devices having structure areas according to an aspect of the invention;

FIG. 4 shows an I-V curve for devices subjected to different voltage ramp rates according to an aspect of the invention;

FIG. 5 shows a ln(I) versus V^{0.5} curve according to an aspect of the invention;

FIG. 6 shows an example of line-to-line spacing determination results for a plurality of test macros according to an aspect of the invention;

FIG. 7 shows a correspondence between a measured line-to-line spacing of a device and a line-to-line spacing experimentally determined by a non-destructive combined C-V and I-V methodology according to an aspect of the invention;

FIG. 8 shows an exemplary embodiment of a AreaComb macro according to an aspect of the invention; and

FIG. 9 shows a flow chart for performing a method according to an aspect of the invention.

### DETAILED DESCRIPTION OF THE INVENTION

The invention relates to a system, method and structure for a fast, non-destructive testing, independent of TDDB, to accurately determine line-to-line spacing for low-k TDDB reliability evaluation and in-line process monitoring. More specifically, the present invention relates to a fast, non-destructive line-to-line spacing determination methodology with combined I-V and C-V measurement and a related testing structure and system, to accurately determine line-to-line spacing for low-k time dependent dielectric breakdown (TDDB) reliability evaluation and in-line processing monitoring. By implementing the present invention, it is now possible to achieve excellent line-to-line spacing determination results, while minimizing the destruction of devices and the time required to perform the analysis.

According to an aspect of the invention, a C-V measurement may be performed on an AreaComb macro structure for all dies. A fast I-V ramp to breakdown may be performed on one or two dies to determine the SE conduction region. Additionally, a non-destructive I-V ramp with a fixed voltage range may be performed on the AreaComb macro testing structure. A slope k_{CA} may be extracted from the capacitance versus area curve of the C-V measurement and a slope k_{SE-control} may be extracted from a ln(I) versus V^{0.5} plot determined from the I-V ramp measurement. Using the experimentally determined slope k_{CA} and the experimentally determined slope k_{SE-control}, a spacing determination of the AreaComb structure may be made. The non-destructive I-V ramp may be repeated on different test macros to determine a slope k_{SE-measured} for that test macro, and the spacing for the test macro may be determined by comparing the slope k_{SE-measured} with the slope k_{SE-control} from the AreaComb analysis.

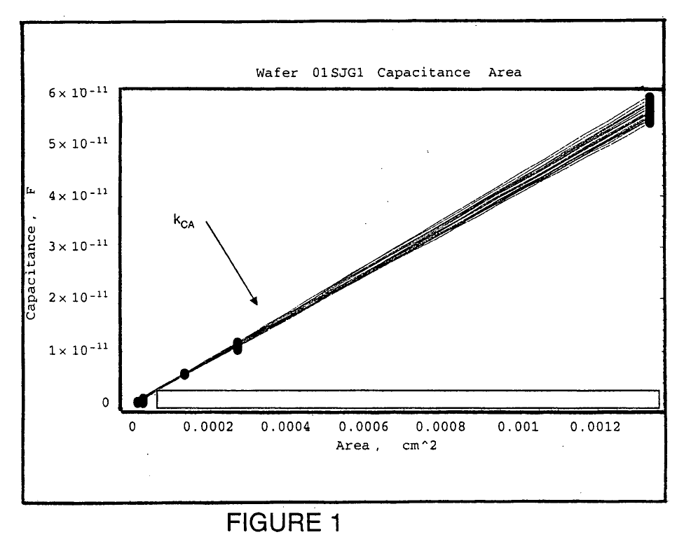

FIG. 1 shows an exemplary plot of capacitance versus area derived from a C-V analysis, according to an aspect of the invention. According to an exemplary embodiment, a C-V plot may be generated by testing an AreaComb macro testing structure at a voltage of 0V, a temperature of 30° Celsius and a frequency of 100 kHz. However, this is only one example of testing conditions, and other testing conditions are contemplated by the invention. The capacitance may be determined according to the following equation:

C=εᵣₛε₀A/s (1)

where A is the tapered trench side wall area (trench height) determined by line length, trench height, and taper angle, s is the line-to-line spacing, εᵣₛ is a static dielectric constant, and ε₀ is a permittivity value in a vacuum, or the dielectric constant of free space.

According to an aspect of the invention, a universal slope k_{CA} may be experimentally determined from the plot of capacitance versus area, as shown in FIG. 1. The experimentally determined slope k_{CA} of the capacitance versus area curve generated by the C-V analysis may be expressed according to the following equation:

k_{CA}=ΔC/ΔA=εᵣₛε₀/s=aε_{rd}ε₀/s (2)

where ε_{rd} is a dynamic dielectric constant and a is a constant.

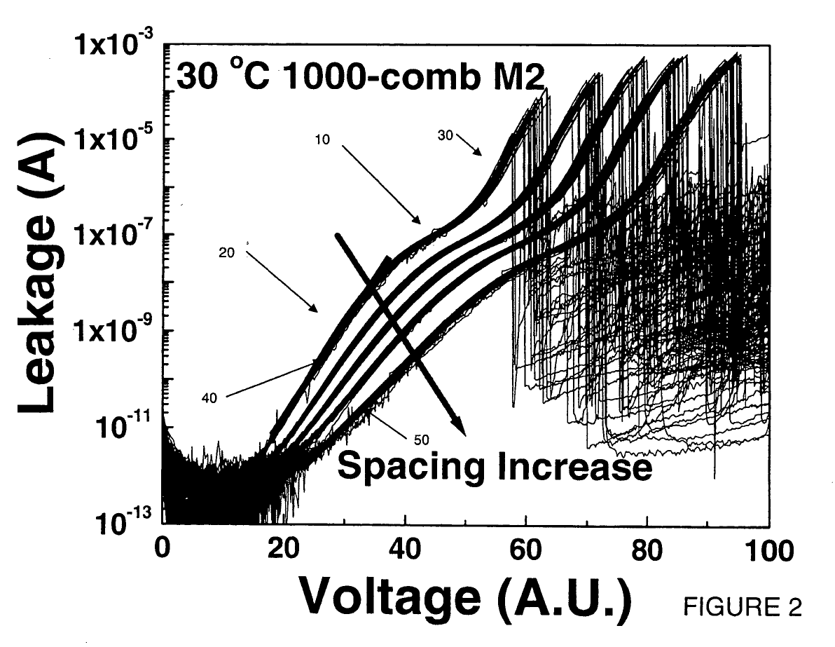

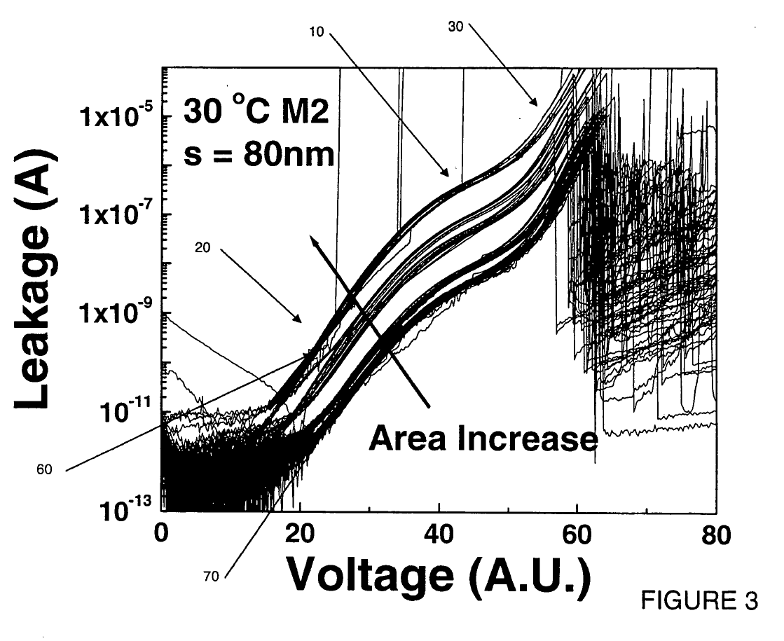

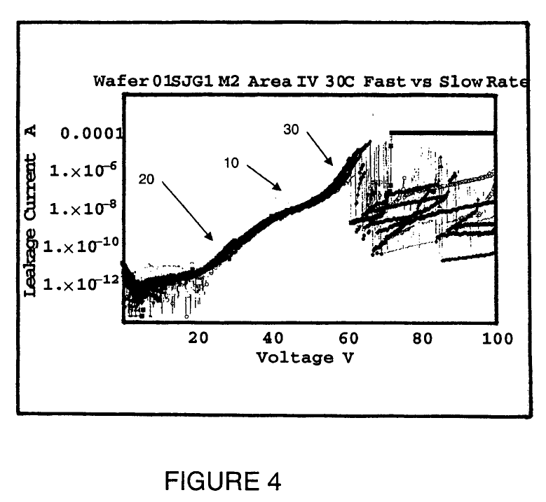

In order to accurately determine a line-to-line spacing, it is desired to provide a test that is less sensitive to test set-ups or test structure layouts (e.g., device area) and test conditions (e.g., temperature, ramp rate), while being more universally sensitive to line spacing. For example, an experimentally determined slope in a Schottky emission (SE) region is very sensitive to different line-to-line spacings (FIG. 2); whereas, the experimentally determined slope in the Schottky emission (SE) region, i.e., below the voltage plateau, is less sensitive to test set-ups and test conditions (FIGS. 3 and 4). Accordingly, in implementation, by using the experimentally-determined slope in the SE region, it is now possible to provide a test which is less sensitive to test set-ups or test structure layouts (e.g., device area) and test conditions (e.g., temperature, ramp rate), while being more universally sensitive to line spacing.

FIGS. 2-4 show examples of I-V plots for a plurality of different testing conditions and set-ups. As shown in FIGS. 2-4, a leakage plateau, or a negative differential resistance (NDR) region 10 may be observed for all the tested samples regardless of different spacings, areas and ramp rates. As explained further below, the NDR region 10 is attributable to the current transition from the Schottky emission (SE) to the Frenkel-Poole (FP) conduction. Further, as is shown in FIGS. 2-4 and explained further below, the slope of the curve in the SE conduction region portion 20 is very sensitive to the line-to-line spacing (FIG. 2), while independent of the test set-ups (e.g., device area) (FIG. 3) and less sensitive to testing conditions (e.g., temperature and ramp rate) (FIG. 4).

FIG. 2 shows an exemplary I-V analysis plot for a plurality of tested devices having different line-to-line spacings. More specifically, FIG. 2 shows the current leakage versus the applied voltage for devices having a range of different line-to-line spacings. As can be observed in FIG. 2, the slopes (e.g., 40 and 50) of the I-V curves for the different line-to-line spacings are very sensitive to spacing change below the leakage plateau 10 (i.e., the slopes below the leakage plateau 10 diverge from one another).

FIG. 3 shows an exemplary I-V analysis plot for a plurality of tested devices having different structure areas. More specifically, FIG. 3 shows the current leakage versus the applied voltage for devices having a range of different structure areas. As shown in FIG. 3, the magnitude of the current leakage for the different devices with different areas vary. However, as can be observed in FIG. 3, the slopes (e.g., 60 and 70) for the different structure areas below the leakage plateau 10 are independent of area change.

FIG. 4 shows an exemplary I-V analysis plot for a plurality of tested devices with different ramp rates. More specifically, FIG. 4 shows the current leakage versus the applied voltage for two voltage ramp dielectric breakdown (VRDB) tests with ramp rates of 1 V/200 ms and 1 V/2000 ms, respectively. As can be observed in FIG. 4, portions of the slopes of the I-V curves for the different ramp rates below the leakage plateau 10 are independent of ramp rate.

As is shown in FIG. 4, the slope in the SE region 20, below the leakage plateau 10, is virtually independent of ramp rate. This is because the Schottky emission is an interface (contact barrier) limited conduction mechanism. Thus, changing voltage ramp rate should have little impact on contact barrier height, and therefore should not affect the Schottky emission leakage current.

In contrast, as further shown in FIG. 4, the slope in the FP region 30, above the leakage plateau (and V_{bd}) 10, exhibits a dependence on ramp rate. This is because the Frenkel-Poole conduction occurs by field-enhanced thermal excitation of trapped electrons. Since electron trapping and de-trapping rate is a strong function of applied voltage ramp rate, the Frenkel-Poole current should be modulated by different ramp rates.

By testing within the SE conduction region, test structure size and test condition sensitivities may be minimized. As explained above, with reference to FIGS. 2-4, the slope in the SE region 20 exhibits the desired testing qualities, e.g., a test that is less sensitive to test set-ups or test structure layouts (e.g., device area) and test conditions (e.g., temperature, ramp rate), while being more universally sensitive to line spacing. Thus, according to an aspect of the invention, a determination of the SE conduction region 20 may be performed.

Also, a fast I-V ramp to breakdown on one or two dies may be performed to determine the SE conduction region 20. As this voltage ramp is to breakdown, these one or two dies will be destroyed. However, according to an aspect of the invention, the fast I-V ramp to breakdown to determine the SE conduction region 20 is the only required destructive testing.

Once the SE region has been determined, a non-destructive I-V ramp within a fixed voltage range may be performed on the AreaComb macro testing structure, to generate an I-V plot. The I-V plot may then be used to generate a plot of ln(I) versus V^{0.5}. By knowing the range of the SE region 20, an applied voltage may be controlled to ensure that the voltage does not ramp beyond the SE region 20 to the voltage plateau 10, or voltage breakdown.

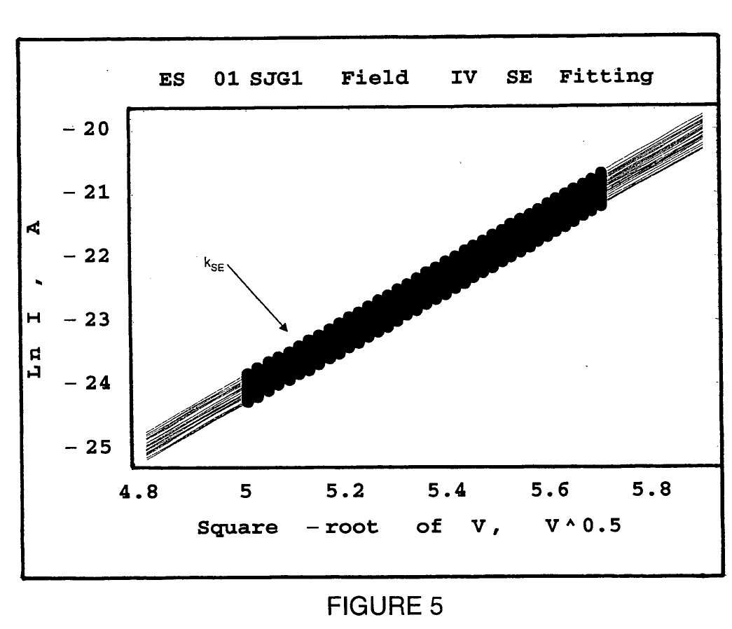

FIG. 5 shows an exemplary plot of ln(I) versus V^{0.5}, according to an aspect of the invention. From this plot of ln(I) versus V^{0.5}, an experimentally determined slope k_{SE-control} may be extracted. As explained further below, the slope k_{SE-control} may be used to determine a line-to-line spacing, as the slope k_{SE-control} is very sensitive to line-to-line spacings. According to an aspect of the invention, by plotting ln(I) versus V^{0.5}, the slope may be described according to the following equation:

k_{SE-control}=β_{SE}/(k_{B}T(s)^{0.5}) (3)

where β_{SE} is a pre-factor of field term, k_{B} is Boltzmann's constant, T is the temperature in Kelvin, and s is the line-to-line spacing.

Additionally, β_{SE} may be described according to the equation:

β_{SE}=(q³/(4πε_{rd}ε₀))^{0.5} (4)

where q is the electric charge and ε_{rd} is the dynamic dielectric constant. As is understood by one skilled in the art β_{SE} is a pre-factor of field term from the Schottky emission conduction region leakage equation, which may be expressed as:

J_{SE}=A*T²exp((β_{SE}(E)^{0.5}−Φ_{SE})/k_{B}T). (5)

According to a further aspect of the invention, using equations (2), (3) and (4), a control line-to-line spacing s_{control} for the AreaComb macro test structure may be extracted from the two experimentally determined slopes k_{CA} and k_{SE-control} without any guessing and knowing of any SE parameters such as dielectric constant and effective Richardson constant A*. Moreover, the experimentally determined slopes, k_{CA} and k_{SE-control}, are based on actual hardware, thus giving an accurate monitoring of line-to-line spacing without any baseline inputs or assumptions. Thus, according to an aspect of the invention, the line-to-line spacing s_{control}, may be described according to the equation:

s_{control}=(a)^{0.5}×(q³/(4πk_{CA}))^{0.5}×1/k_{SE-control}×1/k_{B}T (6)

where (a)^{0.5} is approximately 1.8.

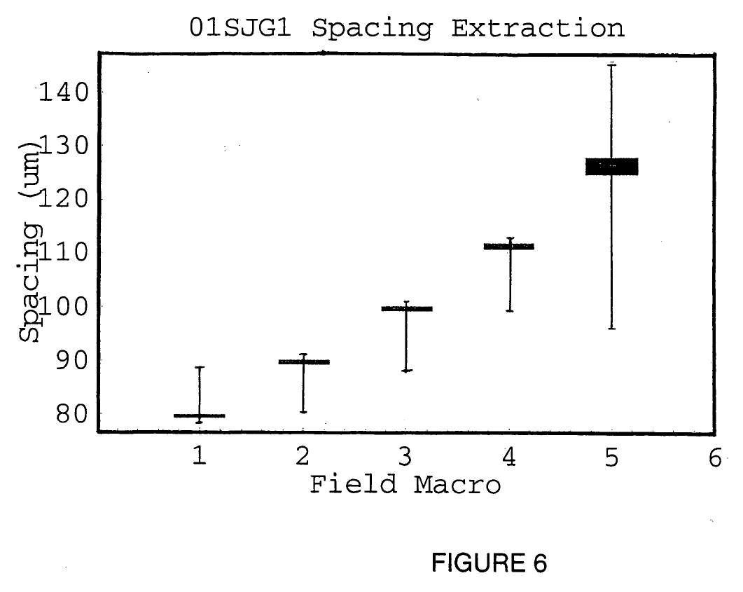

FIG. 6 shows an example of extracted line-to-line spacing for different field macros. A line-to-line spacing s_{measured} for any different test macros may be determined from the control line-to-line spacing s_{control}, determined for the AreaComb macro test structure. A fast I-V ramp may be performed on the test macro in the SE conduction region 20, and a I-V plot may be generated for the test macro. As this voltage ramp test is within the SE region 20 (and thus, not to breakdown), the test is not destructive. Furthermore, according to an aspect of the invention, a plot of ln(I) versus V^{0.5} may be generated for the test macro from the I-V analysis. From this ln(I) versus V^{0.5} plot, a slope k_{SE-measured} may be extracted for the test macro.

More specifically, a line-to-line spacing for the test macro s_{measured} may be determined according to the following equation:

s_{measured}=((k_{SE-measured}×(s_{control})^{0.5})/k_{SE-control})². (7)

Thus, according to the invention, a spacing s_{measured} may be determined for all I-V rampable structures after a reliable k_{CA} parameter extraction for the AreaComb test structure. Furthermore, according to the invention, there is no need to know some critical parameters, e.g., ε, A*, Φ_{SE}, Φ_{PE}, etc.

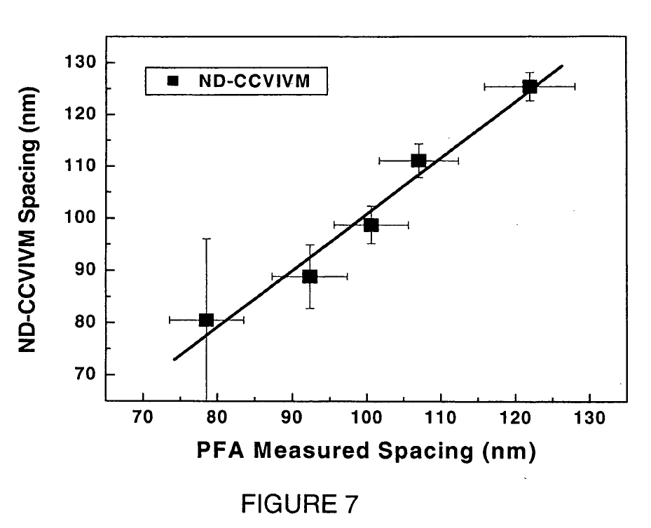

FIG. 7 shows a comparison of line-to-line spacing actually measured in a device with a line-to-line spacing determined according to the present invention, i.e., non-destructive combined C-V and I-V methodology (ND-CCVIVM). As is shown in FIG. 7, there is an excellent agreement between the line-to-line spacing actually measured and the line-to-line spacing determined according to the present invention.

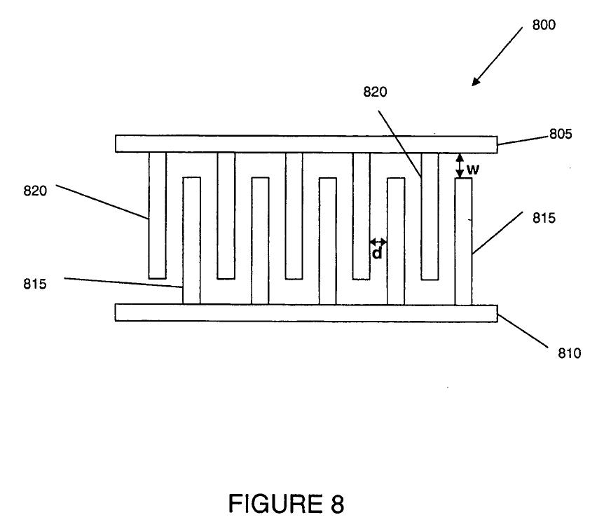

FIG. 8 shows an exemplary embodiment of an AreaComb macro testing structure 800, according to an aspect of the invention. As explained above, the AreaComb macro testing structure 800 may be used to determine a universal slope k_{CA}, from a C-V analysis of the AreaComb macro testing structure 800, and a control k_{SE-control}, from an I-V analysis of the AreaComb macro testing structure 800.

As shown in FIG. 8, the AreaComb macro testing structure 800 may be a comb-comb structure. The comb-comb structure may have 3 to 5 different sizes, with the different sizes at least a five-times size difference (e.g., 100 combs and 500 combs). The comb-comb structure may comprise two parallel base lines 805 and 810, each with a plurality of combs 815 and 820 projecting perpendicularly from the parallel base lines 805 and 810, respectively. Moreover, the projecting combs 815 and 820 from the two parallel base lines 805 and 810 may be interspaced with each other, such that adjacent combs 815 from a single base line 805 are interspaced with a comb 820 from the opposite base line 810.

Additionally, FIG. 8 shows a distance “w” between an end of a comb 815 and the opposite base line 805, and a distance “d” between adjacent oppositely projecting combs 815 and 820. In embodiments, the distance “w” is much greater than the distance “d” to minimize end effect.

By way of an illustrative embodiment, an AreaComb macro may have 100 combs per side (200 combs total), forming a comb-comb structure with a comb length of 100 um. Furthermore, the spacing “d” may be approximately 0.08 um. Additionally, in embodiments, further AreaComb macros may have 500 combs per side, 2500 combs per side and 12500 combs per side. As can be observed, the area ratios for these four exemplary AreaComb macro devices are: 1:5:25:125. Thus, according to an aspect of the invention, the different sizes of the AreaComb macros may be at least a five-times size difference.

### Flow Diagram

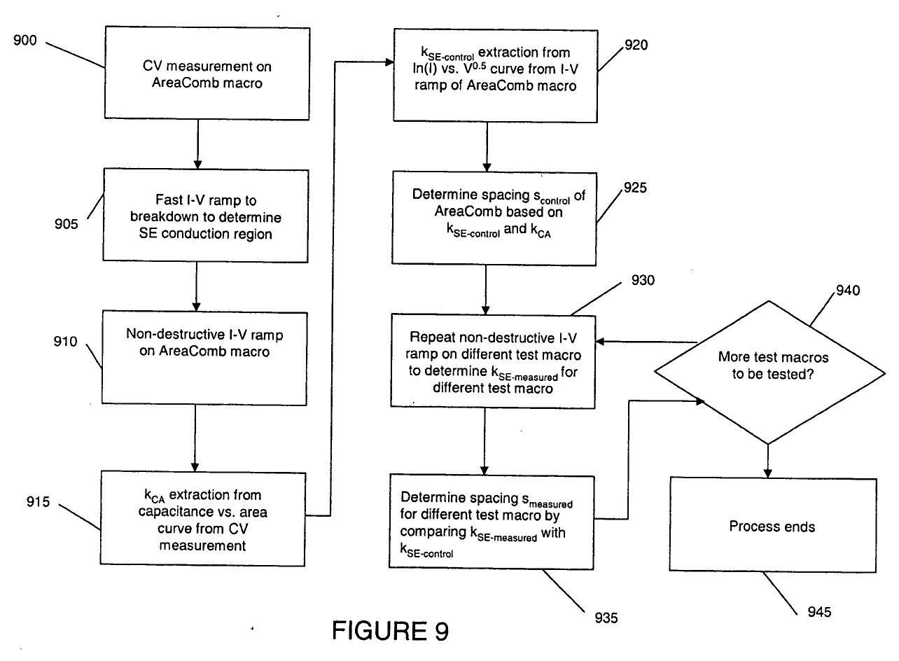

FIG. 9 shows an exemplary flow diagram for implementing steps of the invention, according to an aspect of the invention. The flow diagram may equally represent high-level block diagrams of the invention. The steps of the flow diagram may be implemented and executed from either a server, in a client server relationship, or they may run on a user workstation with operative information conveyed to the user workstation. Additionally, the invention can take the form of an entirely hardware embodiment, an entirely software embodiment or an embodiment containing both hardware and software elements. In an embodiment, the software elements include firmware, resident software, microcode, etc.

Furthermore, the invention can take the form of a computer program product accessible from a computer-usable or computer-readable medium providing program code for use by, or in connection with, a computer or any instruction execution system. For the purposes of this description, a computer-usable or computer readable medium can be any apparatus that can contain, store, communicate, propagate, or transport the program for use by or in connection with the instruction execution system, apparatus, or device. The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk-read only memory (CD-ROM), compact disk-read/write (CD-R/W) and DVD.

Referring to FIG. 9, at step 900, a C-V measurement may be performed on the AreaComb macro test structure. At step 905, a fast I-V ramp may be performed on one or two dies to determine the SE conduction region. At step 910, a non-destructive I-V ramp may be performed on the AreaComb macro test structure in the SE region. At step 915, a slope k_{CA} may be extracted from the capacitance versus area curve from the C-V measurement. At step 920, a k_{SE-control} may be extracted from a ln(I) versus V^{0.5} curve from the I-V ramp of the AreaComb macro test structure. At step 925, a spacing s_{control} of the AreaComb macro testing structure may be determined based on the experimentally determined k_{CA} and k_{SE-control}. At step 930, a non-destructive I-V ramp may be performed on a different test macro to determine a slope k_{SE-measured} for the different test macro. At step 935, a spacing s_{measured} of the different test macro may be determined by comparing k_{SE-measured} with k_{SE-control}.

At step 940, a determination may be made as to whether there are further test macros to be tested. If, at step 940, it is determined that there are more test macros to be tested, the process continues at step 930. If, at step 940, it is determined that there are no other macros to be tested, the process proceeds to step 945. At step 945, the process may end.

Additionally, while the steps of FIG. 9 are shown in a particular order, it should be understood that the steps may be performed in a different order. For example, the extraction of k_{CA} (step 910) may occur before the fast I-V ramp to determine the SE conduction region (step 905). Additionally, for example, the extraction of the slope k_{SE-control} (step 920) may occur before the k_{CA} extraction (step 915).

While the invention has been described in terms of embodiments, those of skill in the art will recognize that the invention can be practiced with modifications and in the spirit and scope of the appended claims.

1-20. (canceled)

21. A method comprising:
experimentally determining a slope k_{CA};
experimentally determining a slope k_{SE}; and
determining a line-to-line spacing of a device from the slope k_{CA} and the slope k_{SE},
wherein the experimentally determining the slope k_{CA} comprises:
performing a C-V measurement of an AreaComb macro, wherein the C-V measurement is performed at a voltage of 0 volts, a temperature of 30° Celsius and a frequency of 100 kHz; and
extracting the slope k_{CA} from a capacitance versus area curve generated from the C-V measurement,
wherein the slope k_{SE} is a slope k_{SE-control} and the experimentally determining the slope k_{SE-control} comprises:
determining a Schottky emission (SE) conduction region, wherein the determining the SE conduction region comprises performing a fast I-V ramp to breakdown at least two dies;
performing an I-V ramp measurement of the AreaComb macro in the SE conduction region,
generating a ln(I) versus V^{0.5} curve from the I-V ramp measurement of the AreaComb macro; and
extracting the slope k_{SE-control} from the ln(I) versus V^{0.5} curve, the method further comprising:
determining a line-to-line spacing s_{control} for the AreaComb macro, wherein the line-to-line spacing s_{control} is determined according to the equation s_{control}=(a)^{0.5}×(q³/(4πk_{CA}))^{0.5}×1/k_{SE-control}×1/k_{B}T, wherein (a)^{0.5} is approximately 1.8;
performing an I-V ramp measurement of a test macro in the SE conduction region;
generating a ln(I) versus V^{0.5} curve from the I-V ramp measurement;
extracting a slope k_{SE-measured} from the ln(I) versus V^{0.5} curve.
comparing k_{SE-control} with k_{SE-measured; and}
determining a line-to-line, via-to-line, or via-to-via spacing s_{measured} for the test macro, wherein a line-to-line, via-to-line, or via-to-via spacing s_{measured} for the test macro is determined according to the equation s_{measured}=((k_{SE-measured}×(s_{control})^{0.5})/k_{SE-control})².

22. A computer program product comprising a computer usable medium having readable program code embodied in the medium, the computer program product includes at least one component to:
experimentally determine an SE conduction region;
experimentally determine a slope k_{CA};
experimentally determine a slope k_{SE}; and
determine a line-to-line spacing of a device from the slope k_{CA} and the slope k_{SE},
wherein:
the at least one component to experimentally determine the slope k_{CA} extracts the slope k_{CA} from a capacitance versus area curve generated from performing a C-V measurement of an AreaComb macro;
the at least one component to experimentally determine the slope k_{SE} determines a slope k_{SE-control} by extracting the slope k_{SE-control} from a ln(I) versus V^{0.5} curve generated from an I-V ramp measurement of the AreaComb macro in the SE conduction region;
the at least one component to determine a line-to-line spacing of a device determines a line-to-line spacing s_{control} for the AreaComb macro according to the equation s_{control=(a)}^{0.5}×(q³/(4πk_{CA}))^{0.5}×1/k_{SE-control}×1/k_{B}T, wherein (a)^{0.5} is approximately 1.8; and
the at least one component to determine a line-to-line spacing of a device extracts a slope k_{SE-measured} from a ln(I) versus V^{0.5} curve generated from an I-V ramp measurement of a test macro in the SE conduction region and determines a line-to-line spacing s_{measured} of a test macro according to the equation s_{measured}=((k_{SE-measured}×(s_{control})^{0.5})/k_{SE-control})².

23. An AreaComb macro structure, comprising:
a plurality of comb-comb structures, wherein each comb-comb structure comprises:
first and second parallel bases;
a plurality of first combs transversely projecting from the first base towards the second base; and
a plurality of second combs transversely projecting from the second base towards the first base, and interspaced with the plurality of first combs in an alternating manner,
wherein:
the plurality of comb-comb structures comprise three to five different sizes;
each of the three to five different sizes of the comb-comb structures is at least a five-times size difference from the other of the comb-comb structures; and
adjacent combs of the plurality of first combs and plurality of second combs are spaced a distance d from one another, and plurality of first combs are spaced from the second base and the plurality of second combs are spaced from the first base a distance h, and wherein h is greater than d.
